(19) United States
(12) Patent Application Publication
(10) Pub. No.: US 2017/0317141 A1
(43) Pub. Date: Nov. 2, 2017

(54) NONVOLATILE SCHOTTKY BARRIER MEMORY TRANSISTOR

(71) Applicant: HGST Netherlands B.V., Amsterdam (NL)

(72) Inventor: Daniel BEDAU, San Jose, CA (US)

(73) Assignee: HGST Netherlands B.V.

(21) Appl. No.: 15/141,765

(22) Filed: Apr. 28, 2016

(51) Int. Cl. H01L 27/24; H01L 45/00; G11C 13/00

(52) U.S. Cl. CPC H01L 27/2463; H01L 45/147; H01L 45/146; H01L 45/1253; H01L 45/1226; G11C 13/0007; H01L 45/1206; G11C 2213/32; G11C 2213/31; G11C 2213/53

(57) ABSTRACT

An apparatus for high density memory with integrated logic. Specifically, a three terminal resistive random access memory (ReRAM) device having Schottky barriers that can switch from a low resistive state to a high resistive state is provided. The Schottky transistor memory device includes an insulating layer, a source region disposed on the insulating layer, a drain region disposed on the insulating layer, a binary or complex oxide memory material, a gate dielectric layer, and a gate electrode. As voltage is applied the Schottky barrier breaks down leading to the formation of a conductive anodic filament (CAF). The CAF is non-volatile and short-circuits the reverse-biased barrier thus keeping the device in a low resistance state. Removing the CAF switches the device back to a high resistance state. Thus, a new type of semiconductor device advantageously combines computation and memory further providing for very high density NAND chains.

### BACKGROUND OF THE DISCLOSURE

### Field of the Disclosure

Embodiments of the present disclosure generally relate to a nonvolatile memory device, specifically a resistive random-access memory (ReRAM) device.

### Description of the Related Art

Nonvolatile memory is computer memory capable of retaining stored information even after having been power cycled. Nonvolatile memory is becoming more popular because of its small size/high density, low power consumption, fast read and write rates, and retention. Flash memory is a common type of nonvolatile memory because of its high density and low fabrication costs. Flash memory is a transistor-based memory device that uses multiple gates per transistor and quantum tunneling for storing the information on its memory device. However, flash memory uses a block-access architecture that can result in long access, erase, and write times. Flash memory also suffers from low endurance, high power consumption, and scaling limitations.

The constantly increasing speed of electronic devices and storage demand drive new requirements for nonvolatile memory. New types of memory, such as resistive random access memory (ReRAM), are being developed as flash memory replacements to meet these demands. Resistive memories refer to technology that uses varying cell resistance to store information. ReRAM refers to the subset that uses metal oxides as the storage medium. In order to switch a ReRAM cell, an external voltage with specific polarity, magnitude, and duration is applied. However, ReRAM typically operates at a significantly high current. As such, ReRAM necessitates a large sized access transistor for each cell which ultimately increases the area and hence the cost.

Thus, there is a need in the art for an improved ReRAM memory device.

### SUMMARY OF THE DISCLOSURE

The present disclosure generally relates to an apparatus for high density memory with integrated logic. Specifically, a three terminal resistive random access memory (ReRAM) device having Schottky barriers that can switch from a low resistive state to a high resistive state is provided. The Schottky transistor memory device includes an insulating layer, a source region disposed on the insulating layer, a drain region disposed on the insulating layer, a binary or complex oxide memory material, a gate dielectric layer, and a gate electrode. As voltage is applied the Schottky barrier breaks down leading to the formation of a conductive anodic filament (CAF). The CAF is non-volatile and short-circuits the reverse-biased barrier thus keeping the device in a low resistance state. Removing the CAF switches the device back to a high resistance state. Thus, a new type of semiconductor device advantageously combines computation and memory further providing for very high density NAND chains.

In one embodiment, a Schottky transistor memory device is disclosed. The device may include an insulating layer, a source region disposed on the insulating layer, and a drain region disposed on the insulating layer. The device may also include an oxide memory material disposed on the insulating layer in between the source region and the drain region. The device may also include a gate dielectric layer disposed on the oxide memory material and a gate electrode disposed on the gate dielectric layer.

In another embodiment, a Schottky transistor memory device is disclosed. The device may include an insulating layer, a source region having a first composition disposed on the insulating layer, and a drain region having a second composition disposed on the insulating layer. The device may also include a memory material having a third composition disposed on the insulating layer in between the source region and the drain region. The third composition of the memory material may be different from the first composition. The device may also include a gate dielectric layer disposed on the memory material and a gate electrode disposed on the gate dielectric layer. The device may also include a conductive anodic filament extending from the drain region to the memory material.

In another embodiment, a memory array is disclosed. The memory array includes one or more Schottky transistor memory devices. At least one of the devices may include an insulating layer, a source region having a first composition disposed on the insulating layer, and a drain region having a second composition disposed on the insulating layer. The device may also include a memory material having a third composition disposed on the insulating layer in between the source region and the drain region. The third composition of the memory material may be different from the first composition. The device may also include a gate dielectric layer disposed on the memory material and a gate electrode disposed on the gate dielectric layer. The device may also include a conductive anodic filament extending from the drain region to the memory material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A shows a schematic illustration of a Schottky transistor memory device according to one embodiment.

FIG. 1B shows a schematic illustration of the Schottky transistor memory device of FIG. 1A after applying voltage.

FIG. 1C shows a schematic illustration of the Schottky transistor memory device of FIG. 1B after a reverse voltage is applied.

FIG. 2A shows a schematic symbol representation of a Schottky transistor memory device according to one embodiment.

FIG. 2B shows a schematic symbol representation of the Schottky transistor memory device of FIG. 2A in a low resistance state.

FIG. 3 shows a schematic illustration of a memory array including one or more Schottky transistor memory devices.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to an apparatus for high density memory with integrated logic. Specifically, a three terminal resistive random access memory (ReRAM) device having Schottky barriers that can switch from a low resistive state to a high resistive state is provided. The Schottky transistor memory device includes an insulating layer, a source region disposed on the insulating layer, a drain region disposed on the insulating layer, an oxide memory material, a gate dielectric layer, and a gate electrode. As voltage is applied the Schottky barrier breaks down leading to the formation of a conductive anodic filament (CAF). The CAF is non-volatile and short-circuits the reverse-biased barrier thus keeping the device in a low resistance state. Removing the CAF switches the device back to a high resistance state. Thus, a new type of semiconductor device advantageously combines computation and memory further providing for very high density NAND chains.

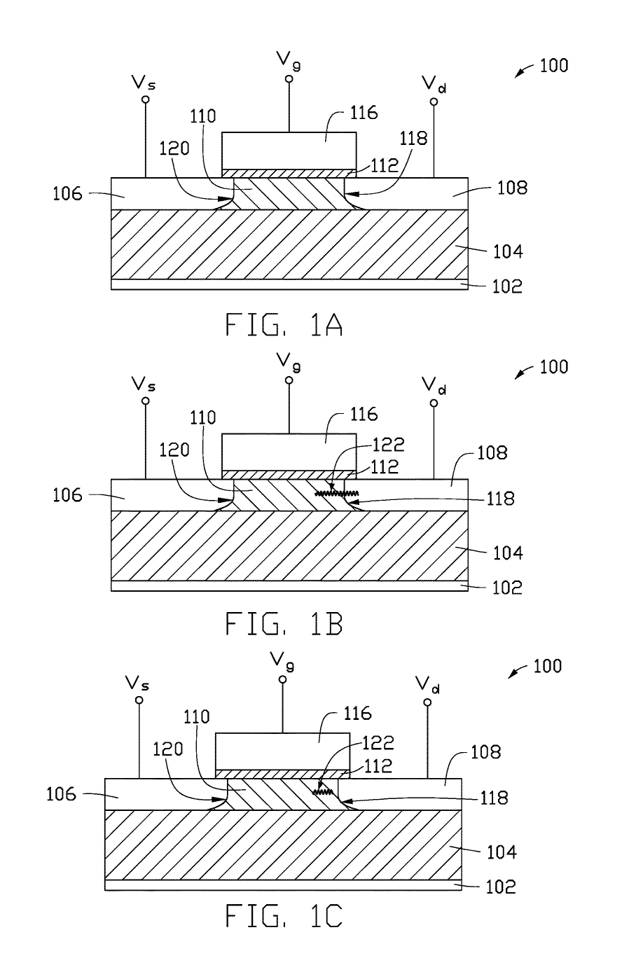

FIG. 1A shows a schematic illustration of a Schottky transistor memory device 100 according to one embodiment. The Schottky transistor memory device 100 may include a substrate 102, an insulating layer 104, a source region 106, a drain region 108, a memory material 110, a gate dielectric layer 112, and a gate electrode 116.

The insulating layer 104 may be disposed on a substrate 102. In one embodiment, the insulating layer 104 comprises silicon dioxide (SiO₂). It is to be understood that other materials are contemplated as well such as silicon nitride and silicon oxynitride. The source region 106 may be disposed on the insulating layer 104. The drain region 108 may be disposed on the insulating layer 104. The memory material 110 may be disposed on the insulating layer 104 in between the source region 106 and the drain region 108. A gate dielectric layer 112 may be disposed on the memory material 110. In one embodiment, the gate dielectric layer 112 may be partially disposed on the source region 106 and partially disposed on the gate region 108. The gate dielectric layer may be silicon dioxide (SiO₂), titanium nitride, hafnium nitride, tungsten oxide, or ruthenium oxide. A gate electrode 116 may be disposed on the gate dielectric layer 112. In one embodiment, the gate electrode 116 extends laterally substantially the same distance as the gate dielectric layer 112. In another embodiment, the gate dielectric layer 112 extends laterally a greater distance than the gate electrode 116. In one embodiment, the gate dielectric layer 112 may be disposed lateral the gate electrode 116 and may extend the height of the gate electrode 116. The gate electrode 116 may be polycrystalline silicon.

The source region 106 and the drain region 108 may be a silicide selected from the group including but not limited to the following: platinum silicide (PtSi), nickel silicide (NiSi), sodium silicide (Na₂Si), magnesium silicide (Mg₂Si), titanium silicide (TiSi₂), tungsten silicide (WSi₂), or of any material forming a Schottky barrier together with the memory material 110. The memory material 110 may be a ReRAM material such as a binary or complex oxide selected from the group including but not limited to the following: zinc oxide (ZnO), titanium oxide (TiO₂), hafnium oxide (HfO₂), tantalum oxide (TaO₂), vanadium oxide (VO₂), tungsten oxide (WO₂), zirconium oxide (ZrO₂), copper oxide, praseodymium calcium manganate (PCMO), or nickel oxide or mixtures thereof.

Two Schottky barriers are formed in the Schottky transistor memory device 100 by the combination of materials used in the source region 106, memory material 110, and drain region 108. A Schottky barrier creates a potential energy barrier for electrons formed at a conductive layer or metal-semiconductor junction. The source region 106 and the drain region 108 may be the metal half of the metal-semiconductor junction while the memory material 110 may act as the semiconductor half of the metal-semiconductor junction. Advantageously, the memory material 110 may also facilitate the formation of a filament, discussed below, providing for different resistive states for a memory device.

One Schottky barrier limits an electrical current in one direction and the other limits a current in the opposite direction. A first Schottky barrier 120 limits an electrical current in a forward direction and is conducting from the source region 106 to the drain region 108. A second Schottky barrier 118 limits an electrical current in the opposite or reverse direction and is isolating from the drain region 108 to the source region 106. When two different resistive states are identified (i.e., a high resistive state and a low resistive state) for a memory device, one state may be associated with a logic “zero,” while the other state may be associated with the logic “one” value. The combination of the two Schottky barriers 118, 120 provides a high resistive state where current cannot flow. The Schottky transistor memory device 100 is in the non-conducting state due to the first Schottky barrier 120 formed at the interface between the source region 106 and memory material 110 and the second Schottky barrier 118 formed at the interface between the drain region 108 and memory material 110. In other words, at zero voltage, the Schottky barriers 118, 120 keep current from flowing between the source region 106 and the drain region 108. As an electrical field or voltage is applied through the gate electrode 116, the Schottky barriers 118, 120 may be switched off and current may flow between the source region 106 and the drain region 108. Utilizing memory material 116 in between the source region 106 and the drain region 108 advantageously provides for filament formation.

FIG. 1B shows a schematic illustration of the Schottky transistor memory device 100 of FIG. 1A after applying voltage. The Schottky transistor memory device 100 may include the substrate 102, the insulating layer 104, the source region 106, the drain region 108, the memory material 110, the gate dielectric layer 112, the gate electrode 116, the first Schottky barrier 120, the second Schottky barrier 118, and a conductive anodic filament (CAF) 122. As voltage is applied to the both the gate electrode 112 and the source region 106, the CAF 122 forms across the memory material 110 to the drain region 108. The large voltage leads to the breakdown of the second Schottky barrier 118 and the CAF 122 formation across the second Schottky barrier 118. After the formation of the CAF 122, the Schottky transistor memory device 100 switches to a low resistance state. The CAF 122 remains even when the voltage is stopped. When two different resistive states are identified (i.e., a high resistive state and a low resistive state) for a ReRAM device, one state may be associated with a logic “zero,” while the other state may be associated with the logic “one” value. As such, the formation of the CAF 122 across the second Schottky barrier 118 provides for a low resistive state or a state associated with either 0 or 1.

FIG. 1C shows a schematic illustration of the Schottky transistor memory device 100 of FIG. 1B after a reverse voltage is applied. The Schottky transistor memory device 100 may include the substrate 102, the insulating layer 104, the source region 106, the drain region 108, the memory material 110, the gate dielectric layer 112, the gate electrode 116, the first Schottky barrier 120, the second Schottky barrier 118, and the CAF 122. To return the Schottky transistor memory device 100 to a high resistive state, the second Schottky barrier 118 is restored. A reverse voltage may be applied to the source region 106. The reverse voltage breaks the CAF 122 and the second Schottky barrier 118 isolates the source region 106 from the drain region 108. Thus the combination of the two Schottky barriers 118, 120 again provides a high resistive state where current cannot flow, thus representing a state associated with either 0 or 1. A portion of the CAF 122 is still present in the memory material 110. A new filament can then be formed by applying voltage to the source region 106 and the gate electrode 116. Thus, CAF 122 formation can be controlled by the polarity of the voltage of the drain and voltage of the source. The CAF 122 formation across the second Schottky barrier 118 advantageously provides for a low resistive state while the CAF 122 breakage and restoration of the second Schottky barrier 118 provides for a high resistive state. The two states thus provide for a nonvolatile memory device in a Schottky transistor. A separate transistor is not required for a ReRAM device advantageously providing for a more compact designed ReRAM device. As such, the present disclosure can be used for ultra-low power non-volatile logic in IoT application.

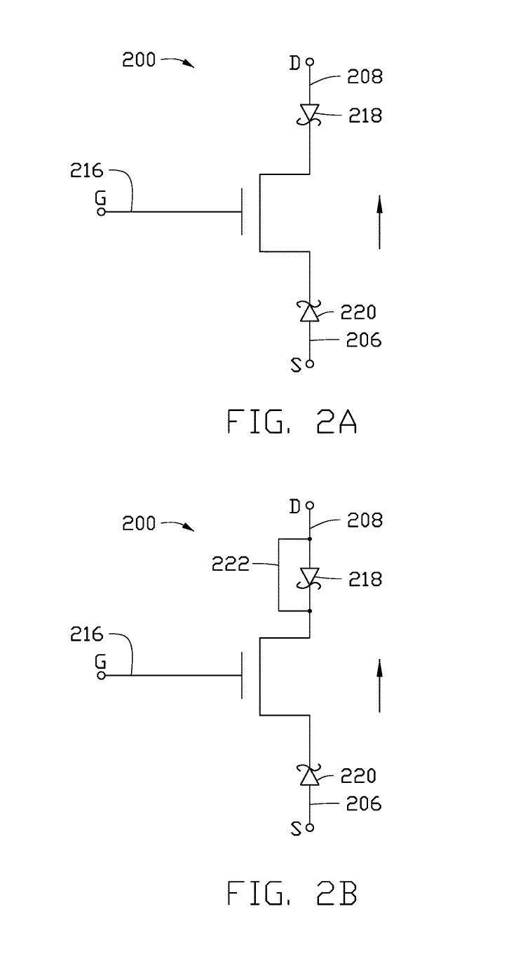

FIG. 2A shows a schematic symbol representation of a Schottky transistor memory device 200 according to one embodiment. The Schottky transistor memory device 200 may be understood to be the Schottky transistor memory device 100 of FIGS. 1A-1C. The schematic shows a gate electrode 216, a source region 206, a drain region 208, a first Schottky barrier 220, and a second Schottky barrier 218. The first Schottky barrier 220 is adjacent the source region 206. The second Schottky barrier 218 is adjacent the drain region 218. A first Schottky barrier 220 limits an electrical current in a forward direction and is conducting from the source region 206 to the drain region 108. A second Schottky barrier 218 limits an electrical current in the opposite or reverse direction and is isolating from the drain region 208 to the source region 206. When two different resistive states are identified (i.e., a high resistive state and a low resistive state) for a memory device, one state may be associated with a logic “zero,” while the other state may be associated with the logic “one” value. The combination of the two Schottky barriers 218, 220 provides a high resistive state where current cannot flow. As current is applied to both the source region 206 and the gate electrode 216, a filament forms.

FIG. 2B shows a schematic symbol representation of the Schottky transistor memory device 200 of FIG. 2A in a low resistance state. The schematic shows the gate electrode 216, the source region 206, the drain region 208, the first Schottky barrier 220, the second Schottky barrier 218, and a CAF 222. The first Schottky barrier 220 is adjacent the source region 206. The second Schottky barrier 218 is adjacent the drain region 218. The CAF 222 provides for current to continue to flow to the drain region 208 breaking the second Schottky barrier 218. The Schottky transistor memory device 200 is thus in a low resistive state. The formation of the CAF 222 across the second Schottky barrier 218 provides for a low resistive state or a state associated with either 0 or 1.

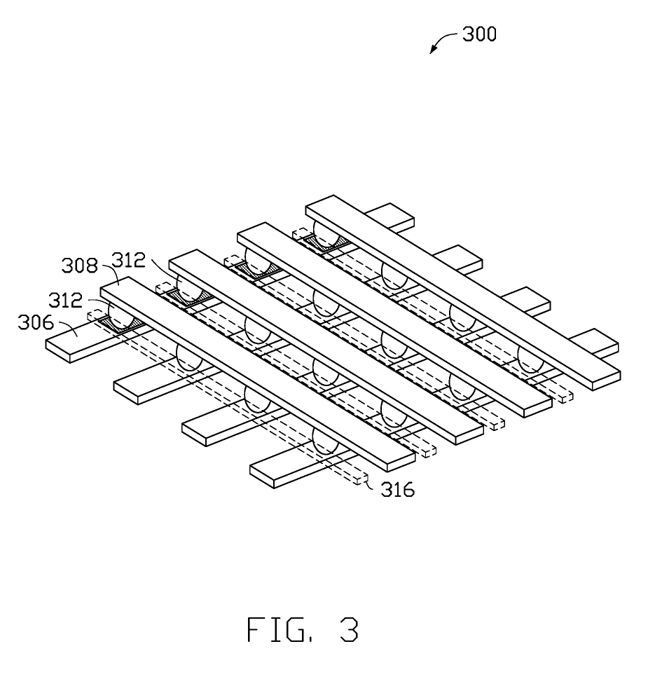

FIG. 3 shows a schematic illustration of a memory array 300 including one or more Schottky transistor memory devices. It should be understood that the memory array 300 may include one or more Schottky transistor devices similar to the Schottky transistor device 100 shown in FIGS. 1A-1C. The memory array may include a source region 306, a drain region 308, a memory material 312, and a gate region 316 (shown in phantom). The source region 306 may contact more than one memory material 312. The drain region 308 may contact more than one memory material 312. The gate electrode 312 may contact more than one memory material. To select a single Schottky transistor memory device, a voltage may be applied to the source region 306 and the gate electrode 316. By applying a voltage to both the source region 306 and gate electrode 316 a CAF, not shown, forms across the memory material 312 to the drain region 308. The large voltage leads to the breakdown of the second Schottky barrier, not shown, and the CAF formation across the second Schottky barrier. After the formation of the CAF, the Schottky transistor memory device 100 switches to a low resistance state representing a state associated with either 0 or 1. Applying a reverse voltage to the source region 306 and gate electrode 316 breaks the CAF and restores the second Schottky barrier. Thus, the second Schottky barrier once again isolates the source region 306 from the drain region 308. The combination of the two Schottky barriers again provides a high resistive state where current cannot flow, thus representing a state associated with either 0 or 1.

The three terminal resistive random access memory device having Schottky barriers can switch from a low resistive state to a high resistive state using the conductive anodic filament. The CAF short-circuits the reverse-biased barrier thus keeping the device in a low resistance state. Removing the CAF switches the device back to a high resistance state. Thus, a new type of semiconductor device advantageously combines computation and memory by having a three terminal structure that is able to switch electronic signals with the additional capability of retaining information when the power is turned off

While the foregoing is directed to embodiments of the present disclosure, other and further embodiments of the disclosure may be devised without departing from the basic scope thereof, and the scope thereof is determined by the claims that follow.

1. A Schottky transistor memory device, comprising:
an insulating layer;
a source region disposed on the insulating layer;
a drain region disposed on the insulating layer;
an oxide memory material disposed on the insulating layer in between the source region and the drain region;
a gate dielectric layer disposed on the oxide memory material; and
a gate electrode disposed on the gate dielectric layer.

2. The device of claim 1, further comprising a first Schottky barrier disposed between the source region and the oxide memory material.

3. The device of claim 2, further comprising a second Schottky barrier disposed between the drain region and the oxide memory material.

4. The device of claim 1, wherein the source region comprises PtSi or NiSi.

5. The device of claim 4, wherein the drain region comprises NiSi.

6. The device of claim 5, wherein the oxide memory material comprises a material selected from the group consisting of the oxides of hafnium, titanium, tantalum zirconium, praseodymium calcium manganate (PCMO).

7. The device of claim 6, wherein the gate electrode comprises polycrystalline silicon.

8. The device of claim 1, wherein the gate dielectric layer is partially disposed on the source region, and partially disposed on the gate region.

9. A Schottky transistor memory device, comprising:
an insulating layer;
a source region disposed on the insulating layer, wherein the source region has a first composition;
a drain region disposed on the insulating layer, wherein the drain region has a second composition;
a memory material disposed on the insulating layer in between the source region and the drain region, wherein the memory material has a third composition different from the first composition;
a gate dielectric layer disposed on the memory material;
a gate electrode disposed on the gate dielectric layer; and
a conductive anodic filament extending from the drain region to the memory material.

10. The device of claim 9, wherein the first composition of the source region comprises PtSi or NiSi.

11. The device of claim 10, wherein the second composition of the drain region comprises PtSi or NiSi.

12. The device of claim 11, wherein the third composition of the memory material comprises an oxide.

13. The device of claim 12, wherein the third composition of the memory material is selected from the group consisting of hafnium oxide, titanium oxide, zirconium oxide, tantalum oxide, praseodymium calcium manganate (PCMO), or mixtures thereof.

14. The device of claim 12, wherein the memory material, one or both of the drain and source regions are chosen from binary or complex oxides such that a Schottky barrier is formed at one or more interfaces.

15. The device of claim 9, wherein the second composition of the drain region comprises PtSi or NiSi.

16. The device of claim 9, wherein the third composition of the memory material is selected from the group consisting of hafnium oxide, titanium oxide, tantalum oxide, praseodymium calcium manganate (PCMO), or mixtures thereof.

17. The device of claim 9, wherein the gate dielectric layer is partially disposed on the source region and partially disposed on the gate region.

18. A memory array comprising one or more Schottky transistor memory devices, at least one of the devices comprising:
an insulating layer;
a source region disposed on the insulating layer, wherein the source region has a first composition;
a drain region disposed on the insulating layer, wherein the drain region has a second composition;
a memory material disposed on the insulating layer in between the source region and the drain region, wherein the memory material has a third composition different from the first composition;
a gate dielectric layer disposed on the memory material;
a gate electrode disposed on the gate dielectric layer; and
a conductive anodic filament extending from the drain region to the memory material.

19. The memory array of claim 18, wherein the first composition of the source region comprises PtSi or NiSi.

20. The memory array of claim 19, wherein the second composition of the drain region comprises PtSi or NiSi.

21. The memory array of claim 20, wherein the third composition of the memory material is selected from the group consisting of hafnium oxide, titanium oxide, tantalum oxide, praseodymium calcium manganate (PCMO), or mixtures thereof.

22. The memory array of claim 18, wherein the third composition of the memory material is selected from the group consisting of hafnium oxide, titanium oxide, tantalum oxide, or mixtures thereof.
